(19) United States
(12) Patent Application Publication
(10) Pub. No.: US 2010/0127333 A1
(43) Pub. Date: May 27, 2010

(54) NOVEL LAYOUT ARCHITECTURE FOR PERFORMANCE ENHANCEMENT

(75) Inventors: Yung-Chin Hou, Taipei (TW); Ta-Pen Guo, Cupertino, CA (US); Harry Chuang, Hsin-Chu City (TW); Carlos H. Diaz, Mountain View, CA (US); Lee-Chung Lu, Taipei (TW); Li-Chun Tien, Tainan (TW); Oscar M. K. Law, Hsinchu (TW); Chih-Chiang Chang, Hsin-Chu Hsien (TW); Chun-Hui Tai, Hsinchu (TW); Jonathan Lee, Banciao City (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/276,172

(22) Filed: Nov. 21, 2008

(51) Int. Cl. H01L 27/092; H01L 27/088

(52) U.S. Cl. 257/368; 257/369; 257/E27.06; 257/E29.104; 257/E27.062

(57) ABSTRACT

The present disclosure provides an integrated circuit. The integrated circuit includes an active region in a semiconductor substrate; a first field effect transistor (FET) disposed in the active region; and an isolation structure disposed in the active region. The FET includes a first gate; a first source formed in the active region and disposed on a first region adjacent the first gate from a first side; and a first drain formed in the active region and disposed on a second region adjacent the first gate from a second side. The isolation structure includes an isolation gate disposed adjacent the first drain; and an isolation source formed in the active region and disposed adjacent the isolation gate such that the isolation source and the first drain are on different sides of the isolation gate.

### BACKGROUND

When a semiconductor device such as a metal-oxide-semiconductor field-effect transistors (MOSFETs) is scaled down through various technology nodes, device packing density and device performance are challenged by device layout and isolation. During a standard-cell-base design, a standard cell will be placed randomly by an auto-placement-route tool. In order to avoid the electrical short problem when a source of a device is adjacent a drain of another device in an inter-cell or intra-cell layout, the following approaches are applied in the standard cell layout design. First, the standard cell layout adopts an isolated active region island to separate the source of one device and the drain of the other device. Second, a space is reserved between the cell boundary and the active region. However, such a discontinuous active region has a poorer device speed and device performance relative to a continuous active region. The reserved space between the source and drain of the different devices cuts off the active region. The reserved space between the active region and the boundary cuts off the active region continuity.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1-2 are top views of a semiconductor structure in various embodiments, constructed according to various aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

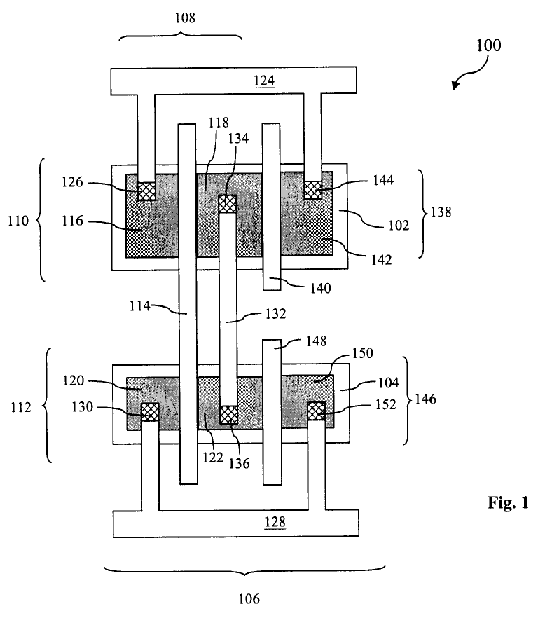

FIG. 1 is a top view of a semiconductor structure 100 constructed according to various aspects of the present disclosure. The semiconductor structure 100 is described below according to one or more embodiments. The semiconductor structure 100 includes a first active region 102 and a second active region 104 defined in a semiconductor substrate (not shown). The semiconductor substrate is a silicon substrate. The semiconductor substrate may alternatively or additionally includes other suitable semiconductor material. Various shallow trench isolation (STI) are formed in the semiconductor substrate such that first and second active regions are determined and separated thereby. The semiconductor substrate in the first active region 102 includes n-type dopant. For example, the first active region 102 includes an n-well formed by an ion implantation. The semiconductor substrate in the second active region 104 includes p-type dopant incorporated therein by an ion implantation or diffusion.

One or more integrated circuit (IC) cells, such as an IC cell 106, are formed in the active regions 102 and 104. The active regions 102 and 104 with multiple IC cells formed thereon are continuous, instead of many sub-active regions 102 separated by isolation features and many sub-active regions 104 separated by isolation features. Therefore the device areas are maximized and furthermore, the device performances are enhanced. In FIG. 1, the IC cell 106 is shown as an example and constructed according to aspects of the present disclosure. The IC cell 106 includes one or more operational field effect transistor (FET) 108. In this example, one p-type metal-oxide-semiconductor (PMOS) transistor 110 and one n-type metal-oxide-semiconductor (NMOS) transistor 112 are provided for illustration. In a particular example, the PMOS 110 and NMOS transistors 112 are configured and coupled as an inverter. The PMOS transistor 110 includes a gate 114 formed in the first active region 102 and is further extended beyond the first active region. The PMOS transistor 110 includes a source 116 and a drain 118 formed in the first active region 102 and disposed on sides of the gate 114 such that the gate 114 is interposed between the source 116 and the drain 118. A channel is defined in the substrate and between the source 116 and drain 118, and underlying the gate 114. The NMOS transistor 112 includes a gate 114 formed in the second active region 104 and is further extended beyond the second active region. In this particular example, the gate of the NMOS transistor 112 and the gate of the PMOS transistor 110 are configured to be connected, therefore labeled with the same reference numeral 114. The NMOS transistor 112 includes a source 120 and a drain 122 formed in the second active region 104 and disposed on sides of the gate 114 such that the gate 114 is interposed between the source 120 and the drain 122.

The source 116 of the PMOS transistor 110 is connected to a power line 124 (or Vdd) for proper bias through a source contact 126. The source 120 of the NMOS transistor 112 is connected to a power line 128 (or Vss) for proper bias through a source contact 130. In this example, the drain 118 of the PMOS transistor 110 and the drain 122 of the NMOS transistor 112 are connected by a conductive feature 132 through a drain contact 134 in the drain 118 and a drain contact 136 in the drain 122.

The IC cell 106 includes an isolation structure 138 formed in the first active region 102 and disposed adjacent the transistor region 108. The isolation structure includes an isolation gate 140 formed in the first active region and disposed adjacent the drain 118. The isolation structure also includes an isolation source 142. In this example, the isolation source 142 is connected to the power line 124 through a contact 144. The IC cell 106 also includes another isolation structure 146 formed in the second active region 104 and disposed adjacent the transistor region 108. The isolation structure 146 includes an isolation gate 148 formed in the second active region and disposed adjacent the drain 122. The isolation structure 146 also includes an isolation source 150. In this example, the isolation source 150 is connected to the power line 128 through a contact 152. In one example, the isolation gates 140 and 148 are floated.

In the structure of the IC cell 106, the source 116 of the operational PMOS transistors and the isolation source 142 of the isolation structure are symmetrically placed on the outer edges of the IC cell such that it is bordered on both sides by sources. Other cells are also configured similarly such that each IC cell is bordered with sources on both boundaries. Each border source can be a source of a operational transistor or an isolation source of an isolation structure according to a particular design of each IC cell. In such a configuration, all IC cells are bordered with sources on both boundaries. Therefore, when the IC cells are placed according to design, only a source from one IC cell is next to a source of an adjacent IC cell. The isolation between the IC cells is automatically maintained. Furthermore, the IC cells are placed on a continuous active region with improved device performance. Similarly, the NMOS transistors and the isolation structure 146 in the second active region 104 are configured such that the IC cell is bordered with sources on both boundaries. At least one of the border sources is an isolation source of an isolation structure. The above example illustrated in FIG. 1 shows one PMOS and one NMOS transistors. However, the operational transistor region 108 may include as many transistors as needed according to design only on the condition that it is bordered by sources on the both boundaries. At least one of the border sources is an isolation source. Each IC cell may have a different number of transistors, different layout and different configuration according to the designed function, the boundary features on both sides are sources, including an isolation source and/or a source of an operational transistor. For example, an array of operational transistors in the same active region (the first or second active regions for example) are placed such that adjacent transistors either share a common source or share a common drain. In another example, the border source of one IC cell may be merged with the border source of the adjacent IC cell to further increase the packing density.

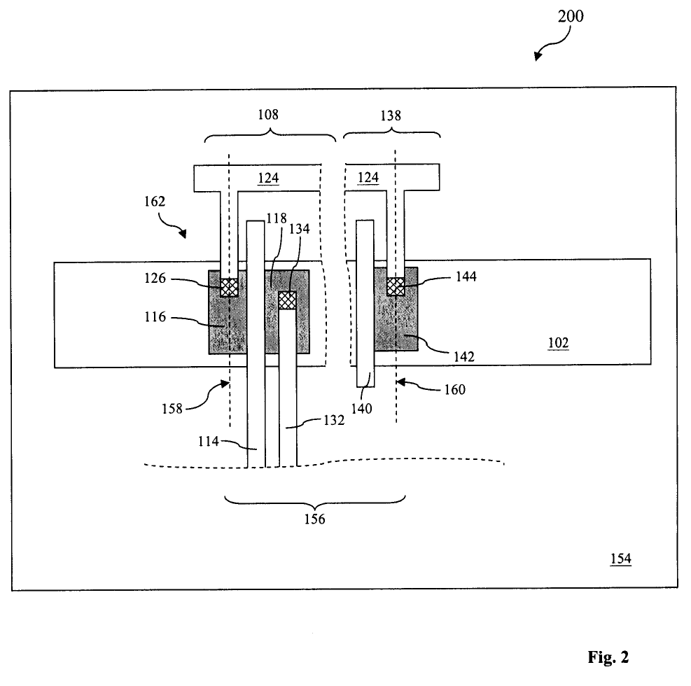

FIG. 2 is a top view of a semiconductor structure 200 according to one or more embodiments and constructed according to aspects of the present disclosure. The semiconductor structure 200 is similar to the semiconductor structure 100 of FIG. 1. Accordingly, similar features in FIGS. 1 and 2 are numbered the same for the sake of simplicity and clarity. The semiconductor structure 200 includes an active region 102 defined in a semiconductor substrate 154. The semiconductor substrate includes silicon and may alternatively or additionally include other suitable semiconductor material. Various isolation features, such as shallow trench isolation (STI), are formed in the semiconductor substrate defining the active region 102 and other active regions, and are separated from each other thereby. The semiconductor substrate in the first active region 102 is doped with a proper dopant, such as an n-type dopant or a p-type dopant, incorporated therein by an ion implantation, diffusion or other suitable technique.

A plurality of integrated circuit (IC) cells are formed in the continuous active region 102. Therefore the performances are enhanced. For illustration, an exemplary IC cell 156 is shown in FIG. 2 and constructed according to aspects of the present disclosure. The IC cell is defined in a region with a first boundary 158 and a second boundary 160. The IC cell 156 is at least partially formed in the active region 102 and may be extended beyond. For example, the IC cell 156 may be extended to another active region with opposite dopant such that both NMOS and PMOS transistors are formed in separate active regions, respectively, and integrated in the IC cell. The IC cell 156 includes an operational transistor region 108 with one or more transistors. In this example, one metal-oxide-semiconductor (MOS) transistor 162 is shown for illustration. In one example, the transistor is a p-type MOS (PMOS) transistor if the active region 102 is n-type doped or an n-type MOS (NMOS) transistor if the active region 102 is p-type doped. The transistor 162 includes a gate 114 formed in the active region 102 and may be further extended beyond the active region. The transistor 162 includes a source 116 and a drain 118 formed in the active region 102 and disposed on a different side of the gate 114 such that the gate 114 is interposed between the source 116 and the drain 118. The source 116 is formed on the boundary line 158 of the IC cell and may further extended out the boundary line 158 form a direction perpendicular to the boundary line 158. A channel is defined in the substrate and configured between the source 116 and drain 118, and underlying the gate 114. The source 116 of the transistor 160 is connected to a power line 124 for proper electrical bias through a source contact 126. In this example, the drain 118 of the transistor 160 is connected a conductive feature 132 through a drain contact 134 for a proper bias or signal.

The IC cell 106 includes an isolation structure 138 formed in the active region 102 and disposed adjacent the transistor region 108. The isolation structure includes an isolation gate 140 formed in the first active region and disposed adjacent the drain 118. The isolation structure also includes an isolation source 142. The source 142 is formed on the boundary line 160 of the IC cell and may further extended out the boundary line 162 form a direction perpendicular to the boundary line 162. In this example, the isolation source 142 is connected to the power line 124 through a contact 144. In one example, the isolation gate 140 is not electrically biased and therefore is floating.

In the structure of the IC cell 106, the source 116 of the transistor 162 and the isolation source 142 of the isolation structure 138 are symmetrically placed on the boundary lines 158 and 160, respectively, such that the IC cell 108 is bordered on both sides by sources. Alternatively, if the transistor region 108 ends up with a drain next to the boundary line 158, then a second isolation structure is added such that the isolation source of the second isolation structure is formed on the boundary. For example, the isolation structure includes a isolation gate disposed between the boundary line 158 and the edge of the transistor region 108. The isolation source of the second isolation structure is formed on the boundary 158 adjacent the isolation gate of the second isolation structure. The isolation source of the second isolation structure is connected to the power line 124 so that the IC cell has consistent boundary sources on both sides. Other cells are also configured similarly such that each IC cell is bordered with sources on both boundaries. Each border source can be a source of a operational transistor or an isolation source of an isolation structure according to a particular design of each IC cell. In such a configuration, all IC cells are bordered with sources on both boundaries. Therefore, when the IC cells are placed according to design, only a source from one IC cell is next to a source of an adjacent IC cell. The isolation between the IC cells is inherently included. Furthermore, the IC cells are placed on a continuous active region with consistent device performance. The above example illustrated in FIG. 2 shows one transistor. However, the operational transistor region 108 may include as many transistors as needed according to design in the condition that it is bordered by sources on the both boundaries. At least one of the boundary sources is an isolation source. Each IC cell may have a different number of transistors, different layout and different configuration according to the designed function. The boundary features on both sides are such configured as sources, including an isolation source and/or a source of an operational transistor. For example, an array of operational transistors in the same active region are placed such that adjacent transistors either share a common source or share a common drain. In another example, the boundary source of one IC cell may be merged with the boundary source of the adjacent IC cell to further increase the packing density. As noted above, the above semiconductor structure 200 may be a portion of the IC cell formed in the active region 102. For example, PMOS transistors are formed in the n-type doped active region and NMOS transistors are formed in the p-type doped active region separated by the STI. NMOS and PMOS transistors are properly configured for a designed circuit function.

One example of the advantages associated with the disclosed structure in one or more embodiments is the consistent device performance since adjacent IC cells are formed in a continuous active region. In another example, the device speed is improved. In another example, there is no device area penalty in the disclosed structure. Other advantages may present in various applications. For example, since only circuit layout is designed differently according to the disclosed structure, there is no change to the fabrication process flow. Therefore, there is no additional masking cost and manufacturing cost.

Although embodiments of the present disclosure have been described in detail, those skilled in the art should understand that they may make various changes, substitutions and alterations herein without departing from the spirit and scope of the present disclosure. In one embodiment, the isolation gate is properly biased to a gate voltage to reduce leakage. In another embodiment, an isolation gate is placed between a source of a first transistor and a drain of a second transistor adjacent the first transistor when they are formed in a continuous active region. In another embodiment, one operational transistor and an isolation structure forms one standard IC cell with the source of the operational transistor and the isolation source are symmetrically placed on the outer edges of the IC cell. Such IC cells can be repeated in a continuous active region according to the designed circuit. The structure of this IC cell will have no isolation issue when placed next to a similar IC cell. Various device features of the semiconductor structures 100 and 200 and the method to make those are further described below according more embodiments. In one example, the semiconductor substrate may alternatively includes other semiconductor material, such as diamond, silicon carbide, gallium arsenic, GaAsP, AlInAs, AlGaAs or GaInP. In furtherance of the above example, the sources and drains are formed in an epitaxy grown semiconductor different from silicon to achieve the strained channel. In one embodiment, the silicon germanium (SiGe) is formed in a first active region by an epitaxy process on the silicon substrate to form the sources and drains of the PMOS transistors. In another embodiment, the silicon carbide (SiC) is formed in a second active region by an epitaxy process on the silicon substrate to form the sources and drains of the NMOS transistors. In another embodiment, the transistor region includes PMOS transistors with source/drain regions of epi SiGe in a first active region of n-type dopant and NMOS transistors with source/drain regions of epi SiC in a second active region of p-type dopant. A channel is defined in the substrate and configured between the source and drain of each transistor, and underlying the associated gate. The channel is thus strained to enable the carrier mobility of the device and enhance the device performance by the spitaxy grown semiconductor.

In another embodiment, a gate in each transistor includes a high k dielectric material layer disposed on the substrate, a metal layer disposed on the high k dielectric material layer. Additionally, an interfacial layer, such as silicon oxide, may be interposed between the high k dielectric material layer and the metal layer. The metal gate for both operational devices and isolation gates are similar in terms of composition, dimension, formation and structure. These gate stacks can be formed in a single process. In one embodiment, a high k dielectric material layer is formed on the semiconductor substrate. A metal gate layer is formed on the high k dielectric material layer. A capping layer is further interposed between the high k dielectric material layer and the metal gate layer. The high k dielectric material layer is formed by a suitable process such as an atomic layer deposition (ALD). Other methods to form the high k dielectric material layer include metal organic chemical vapor deposition (MOCVD), physical vapor deposition (PVD), UV-Ozone Oxidation and molecular beam epitaxy (MBE). In one embodiment, the high k dielectric material includes HfO2. In another embodiment, the high k dielectric material includes Al2O3. Alternatively, the high k dielectric material layer includes metal nitrides, metal silicates or other metal oxides. The metal gate layer is formed by PVD or other suitable process. The metal gate layer includes titanium nitride. In another embodiment, the metal gate layer includes tantalum nitride, molybdenum nitride or titanium aluminum nitride. The capping layer is interposed between the high k dielectric material layer and the metal gate layer. The capping layer includes lanthanum oxide (LaO). The capping layer may alternatively includes other suitable material. Then the various gate material layers are patterned to form gate stacks for both operational devices and the dummy gates. The method to pattern the gate material layers includes applying various dry and wet etching steps, using a patterned mask defining various openings. The gate layers within the openings of the patterned mask are removed by the one or etching processes.

In another embodiment, the semiconductor substrate may include a semiconductor-on-insulator (SOI) structure such as a buried dielectric layer. Alternatively, the substrate may include a buried dielectric layer such as a buried oxide (BOX) layer, such as that formed by a method referred to as separation by implantation of oxygen (SIMOX) technology, wafer bonding, selective epitaxial growth (SEG), or other proper method. In another embodiment, the formation of STI may include etching a trench in a substrate and filling the trench by insulator materials such as silicon oxide, silicon nitride, or silicon oxynitride. The filled trench may have a multi-layer structure such as a thermal oxide liner layer with silicon nitride filling the trench. In one embodiment, the STI structure may be created using a process sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical planarization (CMP) to etch back, and using nitride stripping to leave the STI structure.

One or more ion implantation steps are further performed to form various sources and drains, and/or light doped drain (LDD) features. In one example, the LDD regions are formed after the formation of the gate stack and/or the epi source and drain region, and therefore aligned with the gates. A gate spacer may be formed on the sidewalls of the metal gate stack. Then heavy source and drain doping processes are performed to form heavy doped sources and drains, and therefore the heavy doped sources and drains are substantially aligned with the outer edges of the spacers. The gate spacers may have a multilayer structure and may include silicon oxide, silicon nitride, silicon oxynitride, or other dielectric material. The doped source and drain regions and LDD regions of either an n-type dopant or a p-type dopant are formed by a conventional doping process such as ion implantation. N-type dopant impurities employed to form the associated doped regions may include phosphorus, arsenic, and/or other materials. P-type dopant impurities may include boron, indium, and/or other materials. silicide are formed on the sources and drains to reduce the contact resistance. Then silicide can be formed on the sources and drains by a process including depositing a metal layer, annealing the metal layer such that the metal layer is able to react with silicon to form silicide, and then removing the non-reacted metal layer.

Then an inter-level dielectric (ILD) layer is formed on the substrate and a chemical mechanical polishing (CMP) process is further applied to the substrate to polish the substrate. In another example, an etch stop layer (ESL) is formed on top of the gate stacks before forming the ILD layer. In one embodiment, the gate stacks formed above are final metal gate structure and remain in the final circuit. In another embodiment, the thus formed gate stacks are partially removed and then refilled with proper materials for various fabrication consideration such as thermal budget. In this case, the CMP process is continued until the polysilicon surface is exposed. In another embodiment, the CMP process is stopped on the hard mask layer and then the hard mask is removed by a wet etching process.

A multilayer interconnection (MLI) is formed on the substrate to electrically connect various device features to form a functional circuit. The multilayer interconnection includes vertical interconnects, such as conventional vias or contacts, and horizontal interconnects, such as metal lines. The various interconnection features may implement various conductive materials including copper, tungsten and silicide. In one example, a damascene process is used to form copper related multilayer interconnection structure. In another embodiment, tungsten is used to form tungsten plug in the contact holes.

The semiconductor structure 100 or 200 serves only as examples. The transistors may be alternatively other type of field effect transistors (FET). The semiconductor structure 100 or 200 may be used in various applications such as digital circuit, imaging sensor devices, dynamic random access memory (DRAM) cell, and/or other microelectronic devices. In another embodiment, the semiconductor structure 100 or 200 includes FinFET transistors. Of course, aspects of the present disclosure are also applicable and/or readily adaptable to other type of transistor and may be employed in many different applications, including sensor cells, memory cells, logic cells, and others.

Thus, the present disclosure provides an integrated circuit. The integrated circuit includes an active region in a semiconductor substrate; a first field effect transistor (FET) disposed in the active region; and an isolation structure disposed in the active region. The FET includes a first gate; a first source formed in the active region and disposed on a first region adjacent the first gate from a first side; and a first drain formed in the active region and disposed on a second region adjacent the first gate from a second side. The isolation structure includes an isolation gate disposed adjacent the first drain; and an isolation source formed in the active region and disposed adjacent the isolation gate such that the isolation source and the first drain are on different sides of the isolation gate.

The integrated circuit may further include a second FET formed in the active region and disposed adjacent the isolation structure. The second FET includes a second gate; a second source formed in the active region and interposed between the isolation source and the first gate; and a second drain formed in the active region and positioned such that the second gate is interposed between the second source and the second drain. Alternatively, the second FET includes a second gate adjacent the isolation source; and a second drain formed in the active region and positioned such that the second gate is interposed between the isolation source and the second drain, in which the isolation source is configured to function as a source of the second FET. In the disclosed integrated circuit, the isolation source may be biased such that the first FET and other FET disposed on other side of the isolation structure are electrically isolated from each other by the isolation structure.

The present disclosure also provides an integrated circuit (IC) in another embodiment. The integrated circuit includes an active region in a semiconductor substrate; and a first IC cell formed in the active region, the first IC cell defines a first boundary and a second boundary. The first IC cell includes at least one field effect transistor (FET) having a first source disposed on the first boundary; a first gate disposed on the semiconductor substrate and adjacent the first source; and a first drain positioned such that the first gate is interposed between the first source and the first drain. The first IC cell also includes a first isolation structure including a first isolation gate disposed adjacent the first drain; and a first isolation source formed on the second boundary and adjacent the first isolation gate such that the first IC cell has the first source and the first isolation source symmetrically disposed on the first and second boundary, respectively.

The integrated circuit may further include a second IC cell formed in the active region and disposed adjacent to the first IC cell, wherein the second IC cell defines a third boundary and a fourth boundary, the third boundary overlaps the second boundary. The second IC cell includes at least one FET having a second source disposed on the third boundary; a second gate disposed on the semiconductor substrate and adjacent the second source; and a second drain positioned such that the second gate is interposed between the second source and the second drain. The second IC cell also includes a second isolation structure including a second isolation gate disposed adjacent the second drain; and a second isolation source formed on the fourth boundary and adjacent the second isolation gate such that the second IC cell has the second source and the second isolation source symmetrically disposed on the third and fourth boundary, respectively. In the integrated circuit, the second source and the first isolation source may overlap and be configured for proper function of the second IC cell. The integrated circuit may further include a third second IC cell formed in the active region and disposed adjacent to the first IC cell, wherein the third IC cell defines a fifth boundary and a sixth boundary, the sixth boundary overlaps the first boundary. The third IC cell includes at least one FET having a third source disposed on the fifth boundary; a third gate disposed on the semiconductor substrate and adjacent the third source; and a third drain positioned such that the third gate is interposed between the third source and the third drain. The third IC cell also includes a third isolation structure including a third isolation gate disposed adjacent the third drain; and a third isolation source formed on the sixth boundary and adjacent the third isolation gate such that the third IC cell has the third source and the third isolation source symmetrically disposed on the fifth and sixth boundary, respectively. The third isolation source and the first source may overlap and be configured for proper function of the third IC cell. The first isolation gate may be electrically floating. The FET includes a p-type metal-oxide-semiconductor field-effect transistor (PMOSFET). Alternatively, the FET includes an n-type MOSFET (NMOSFET).

The present disclosure also provides an integrated circuit in another embodiment. The integrated circuit includes a semiconductor substrate; a first active region defined in the semiconductor substrate and having an n-type dopant; a second active region defined in the semiconductor substrate, separated from the first active region by an isolation feature and having a p-type dopant; a first p-type metal-oxide-semiconductor (PMOS) transistor formed in the first active region; a first n-type metal-oxide-semiconductor (NMOS) transistor formed in the second active region; a first isolation structure formed in the first active region; and a second isolation structure formed in the second active region. The first PMOS transistor includes a first source and a first drain formed in the first active region; and a first gate formed on the semiconductor substrate and interposed between the first source and first drain. The first NMOS transistor includes a second source and a second drain formed in the second active region; and a second gate formed on the semiconductor substrate and interposed between the second source and second drain. The first isolation structure includes a first isolation gate disposed adjacent the first drain; and a first isolation source positioned such that the first isolation gate is interposed between the first drain and first isolation source. The second isolation structure includes a second isolation gate disposed adjacent the second drain; and a second isolation source positioned such that the second isolation gate is interposed between the second drain and second isolation source.

In the disclosed integrated circuit, the first gate and the second gate may be extended to connect each other; and the first drain and the second drain are electrically connected. The first source and the first isolation source may be electrically connected to a power line Vdd; and the second source and the second isolation source may be electrically connected to a power line Vss. The first isolation source is connected to the power line Vdd for electrically isolating a second PMOS transistor disposed adjacent the first isolation structure from the first PMOS transistor. The second isolation source may be connected to the power line Vss for electrically isolating a second NMOS transistor disposed adjacent the second isolation structure from the first NMOS transistor. The integrated circuit may further include a second PMOS transistor formed in the first active region and adjacent the first PMOS transistor, the second PMOS includes a third gate adjacent the first source; a third drain positioned such that the third gate is interposed between the third drain and the first source; and a second NMOS transistor formed in the second active region and adjacent the first NMOS transistor, the second NMOS includes a fourth gate adjacent the second source; a fourth drain positioned such that the fourth gate is interposed between the fourth drain and the second source. The first gate and the first isolation gate each may include a first metal; and the second gate and the second isolation each comprises a second metal different from the first metal. The first source and the first drain may include silicon geranium (SiGe); and the second source and the second drain may include silicon carbide (SiC).

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit, comprising:
an active region in a semiconductor substrate;
a first field effect transistor (FET) disposed in the active region, wherein the FET includes:
a first gate;
a first source formed in the active region and disposed on a first region adjacent the first gate; and
a first drain formed in the active region and disposed on a second region adjacent the first gate; and
an isolation structure disposed in the active region, wherein the isolation structure includes:
an isolation gate disposed adjacent the first drain; and
an isolation source formed in the active region and disposed adjacent the isolation gate such that the isolation source and the first drain are on different sides of the isolation gate.

2. The integrated circuit of claim 1, further comprising a second FET formed in the active region and disposed adjacent the isolation structure, wherein the second FET includes:
a second gate;
a second source formed in the active region and interposed between the isolation source and the first gate; and
a second drain formed in the active region and positioned such that the second gate is interposed between the second source and the second drain.

3. The integrated circuit of claim 1, further comprising a second FET formed in the active region and disposed adjacent the isolation structure, wherein the second FET includes:
a second gate adjacent the isolation source; and
a second drain formed in the active region and positioned such that the second gate is interposed between the isolation source and the second drain,
wherein the isolation source is configured to function as a source of the second FET.

4. The integrated circuit of claim 1, wherein the isolation source is biased such that the first FET and another FET disposed on the other side of the isolation structure are electrically isolated from each other by the isolation structure.

5. An integrated circuit (IC), comprising:
an active region in a semiconductor substrate; and
a first IC cell formed in the active region, the first IC cell defines a first boundary and a second boundary, and the first IC cell includes:
at least one field effect transistor (FET) having a first source disposed on the first boundary; a first gate disposed on the semiconductor substrate and adjacent the first source; and a first drain positioned such that the first gate is interposed between the first source and the first drain; and
a first isolation structure including:
a first isolation gate disposed adjacent the first drain; and
a first isolation source formed on the second boundary and adjacent the first isolation gate such that the first IC cell has the first source and the first isolation source symmetrically disposed on the first and second boundary, respectively.

6. The integrated circuit of claim 5, further comprising a second IC cell formed in the active region and disposed adjacent to the first IC cell, wherein the second IC cell defines a third boundary and a fourth boundary, the third boundary overlaps the second boundary, and the second IC cell includes:
at least one FET having a second source disposed on the third boundary; a second gate disposed on the semiconductor substrate and adjacent the second source; and a second drain positioned such that the second gate is interposed between the second source and the second drain; and
a second isolation structure including:
a second isolation gate disposed adjacent the second drain; and
a second isolation source formed on the fourth boundary and adjacent the second isolation gate such that the second IC cell has the second source and the second isolation source symmetrically disposed on the third and fourth boundary, respectively.

7. The integrated circuit of claim 6, wherein the second source and the first isolation source overlap and are configured for proper function of the second IC cell.

8. The integrated circuit of claim 6, further comprising a third second IC cell formed in the active region and disposed adjacent to the first IC cell, wherein the third IC cell defines a fifth boundary and a sixth boundary, the sixth boundary overlaps the first boundary, and the third IC cell includes:
at least one FET having a third source disposed on the fifth boundary; a third gate disposed on the semiconductor substrate and adjacent the third source; and a third drain positioned such that the third gate is interposed between the third source and the third drain; and
a third isolation structure including:
a third isolation gate disposed adjacent the third drain; and
a third isolation source formed on the sixth boundary and adjacent the third isolation gate such that the third IC cell has the third source and the third isolation source symmetrically disposed on the fifth and sixth boundary, respectively.

9. The integrated circuit of claim 8, wherein the third isolation source and the first source overlap and are configured for proper function of the third IC cell.

10. The integrated circuit of claim 5, wherein the first isolation gate is electrically floating.

11. The integrated circuit of claim 5, wherein the FET comprises a p-type metal-oxide-semiconductor field-effect transistor (PMOSFET).

12. The integrated circuit of claim 5, wherein the FET comprises an n-type MOSFET (NMOSFET).

13. An integrated circuit, comprising:
a semiconductor substrate;
a first active region defined in the semiconductor substrate and having an n-type dopant;
a second active region defined in the semiconductor substrate, separated from the first active region by an isolation feature and having a p-type dopant;
a first p-type metal-oxide-semiconductor (PMOS) transistor formed in the first active region, wherein the first PMOS transistor includes:
a first source and a first drain formed in the first active region; and
a first gate formed on the semiconductor substrate and interposed between the first source and first drain;
a first n-type metal-oxide-semiconductor (NMOS) transistor formed in the second active region, wherein the first NMOS transistor includes:
a second source and a second drain formed in the second active region; and
a second gate formed on the semiconductor substrate and interposed between the second source and second drain;
a first isolation structure formed in the first active region, wherein the first isolation structure includes:
a first isolation gate disposed adjacent the first drain; and
a first isolation source positioned such that the first isolation gate is interposed between the first drain and first isolation source; and
a second isolation structure formed in the second active region, wherein the second isolation structure includes:
a second isolation gate disposed adjacent the second drain; and
a second isolation source positioned such that the second isolation gate is interposed between the second drain and second isolation source.

14. The integrated circuit of claim 13, wherein the first gate and the second gate are extended to connect each other; and the first drain and the second drain are electrically connected.

15. The integrated circuit of claim 13, wherein the first source and the first isolation source are electrically connected to a power line Vdd and wherein the second source and the second isolation source are electrically connected to a power line Vss.

16. The integrated circuit of claim 15, wherein the first isolation source is connected to the power line Vdd for electrically isolating a second PMOS transistor disposed adjacent the first isolation structure from the first PMOS transistor.

17. The integrated circuit of claim 15, wherein the second isolation source is connected to the power line Vss for electrically isolating a second NMOS transistor disposed adjacent the second isolation structure from the first NMOS transistor.

18. The integrated circuit of claim 13, further comprising
a second PMOS transistor formed in the first active region and adjacent the first PMOS transistor, the second PMOS includes a third gate adjacent the first source; a third drain positioned such that the third gate is interposed between the third drain and the first source; and
a second NMOS transistor formed in the second active region and adjacent the first NMOS transistor, the second NMOS includes a fourth gate adjacent the second source; a fourth drain positioned such that the fourth gate is interposed between the fourth drain and the second source.

19. The integrated circuit of claim 13, wherein the first gate and the first isolation gate each comprises a first metal and wherein the second gate and the second isolation each comprises a second metal different from the first metal.

20. The integrated circuit of claim 13, wherein the first source and the first drain comprise silicon geranium (SiGe) and wherein the second source and the second drain comprise silicon carbide (SiC).
